(19) United States
(12) Patent Application Publication
(10) Pub. No.: US 2025/0366107 A1
(43) Pub. Date: Nov. 27, 2025

(54) SYSTEM AND METHODS FOR SHAPED EPITAXIAL STRESSORS

(71) Applicant: Samsung Electronics Co., Ltd., Suwon-si (KR)

(72) Inventors: Aravindh KUMAR, Mountain View, CA (US); Mehdi SAREMI, Danville, CA (US); Ming HE, San Jose, CA (US); Muhammed AHOSAN UL KARIM, San Jose, CA (US); Rebecca PARK, Mountain View, CA (US); Harsono SIMKA, Saratoga, CA (US)

(21) Appl. No.: 19/206,584

(22) Filed: May 13, 2025

Related U.S. Application Data
(60) Provisional application No. 63/650,396, filed on May 21, 2024.

(51) Int. Cl. H10D 62/13; H10D 30/00; H10D 30/01; H10D 62/00

(52) U.S. Cl. CPC H10D 62/151; H10D 30/019; H10D 30/501; H10D 62/021

(57) ABSTRACT

Disclosed herein are methods, devices and systems including a substrate, a transistor channel on the substrate and extending in direction parallel to the substrate, a first electrode extending in a direction orthogonal to the substrate and coupled to the transistor channel, a second electrode coupled to the transistor channel and extending in a direction orthogonal to the substrate and parallel to the first electrode, and a first epitaxial structure arranged between the transistor channel and the first electrode. The first epitaxial structure may share a common crystalline orientation with the transistor channel, and may separate a surface of the first electrode and a surface of the transistor channel in a direction parallel to the substrate by a distance varying along the length of the first electrode.

### CROSS-REFERENCE TO RELATED APPLICATION

This application claims the priority benefit under 35 U.S.C. § 119 (e) of U.S. Provisional Patent Application Ser. No. 63/650,396 filed on May 21, 2024, the disclosure of which is incorporated herein by reference in its entirety.

### TECHNICAL FIELD

The subject matter disclosed herein relates to microelectronics and integrated circuits (IC) structures. More particularly, the subject matter disclosed herein relates to a semiconductor structure involving shaped epitaxial structures.

### BACKGROUND

Semiconductor devices may be created using complex three-dimensional structures made up of sets of smaller components. Such components may include circuit components such as transistors, capacitors, etc. reproduced in large numbers and addressed using a matrix of intersecting lines. However, forming a three-dimension address matrix is complex and may face difficulties in forming the conductive lines, ensuring sufficient isolation between the individual lines, and ensuring the desired properties are present within materials. It is further noted that background concepts discussed herein are for informational purposes only and are not intended to limit the present disclosure. Nor should the background or field described herein be intended to limit the disclosure herein to a particular use or concept.

### SUMMARY

An example embodiment provides a device including a substrate, a transistor channel on the substrate and extending in direction parallel to the substrate, a first electrode extending in a direction orthogonal to the substrate and coupled to the transistor channel, a second electrode coupled to the transistor channel and extending in a direction orthogonal to the substrate and parallel to the first electrode, and a first epitaxial structure arranged between the transistor channel and the first electrode. The first epitaxial structure may share a common crystalline orientation with the transistor channel, and may separate a surface of the first electrode and a surface of the transistor channel in a direction parallel to the substrate by a distance varying along the length of the first electrode. The first epitaxial structure may be between the first electrode and the substrate, and the first epitaxial structure may form a concave surface with respect to the first electrode. The second electrode may surround the transistor channel and form a gate-all-around transistor. An inner spacer may be between the first electrode, the second electrode and the transistor channel with the first electrode between the first epitaxial structure and the inner spacer. The distance between a surface of the first electrode and a surface of the transistor channel in a direction parallel to the substrate may be inversely related to the distance to the substrate in a direction parallel to the first electrode. The first electrode may be between the first epitaxial structure and the substrate, and the first epitaxial structure may form a convex surface with respect to the first electrode. A third electrode may couple to the transistor channel and extend in a direction orthogonal to the substrate with a second epitaxial structure between the third electrode and the transistor channel. The first electrode may be coupled to the third electrode via the transistor channel.

An example embodiment provides a device including a substrate with a transistor channel extending in direction parallel to the substrate, a first electrode may couple to a first end of the transistor channel and may extend in a direction orthogonal to the substrate, a second electrode may couple to a second end of the transistor channel and extend in a direction parallel to the first electrode. A first epitaxial structure may be between the first electrode and the first end of the transistor channel and have a thickness varying along a direction parallel to the first electrode. A second epitaxial structure may be between the second electrode and the second end of the transistor channel and have a thickness varying along a direction parallel to the second electrode. The first epitaxial structure may be between the first electrode and the substrate and may form a concave surface with respect to the electrode. The first electrode may be between the first epitaxial structure and the substrate, and the first epitaxial structure may form a convex surface with respect to first electrode. A third electrode may be between the first electrode and the second electrode, the third electrode extending in a direction parallel to the first electrode and second electrode, with the third electrode electrically coupled to the transistor channel along a medial section between the first end and the second end. The transistor channel may be formed from silicon and the first epitaxial structure may be formed from silicon. A dielectric material may be between the transistor channel and the substrate.

An example embodiment provides a method including forming an epitaxial stack on a substrate, the epitaxial including a transistor channel; removing a portion of the epitaxial stack to form a trench exposing at least a portion of the substrate; forming an epitaxial structure within the trench, the epitaxial structure contacting the transistor channel; imparting a compressive stress along the length of the transistor channel via the epitaxial structure; and depositing a first electrode in the trench. Forming the epitaxial structure may include growing a non-contiguous epitaxial layer, the epitaxial structure forming a concave surface with respect to the first electrode, and the epitaxial structure between the first electrode and the substrate. Imparting compressive stress on the epitaxial structure along the length of the transistor channel via the epitaxial structure may include forming a dummy stressor within the trench, the dummy stressor imparting compressive stress on the epitaxial structure, the epitaxial structure transferring the compressive stress to the transistor channel. Forming the epitaxial structure may include growing an epitaxial layer and etching the epitaxial layer to reduce a distance between the transistor channel and the first electrode. The first electrode may be a drain electrode or a source electrode. After imparting compressive stress on the transistor channel along the length of the transistor channel via the epitaxial structure, a barrier layer may be formed on a surface of the epitaxial structure such that the first electrode contacts the barrier layer.

### BRIEF DESCRIPTION OF THE DRAWING

In the following section, the aspects of the subject matter disclosed herein will be described with reference to example embodiments illustrated in the figures, in which:

FIG. 1A depicts a cross-sectional view of a semiconductor structure according to various embodiments of the subject matter disclosed herein;

FIG. 1B depicts a perspective view of a semiconductor structure according to various embodiments of the subject matter disclosed herein;

FIG. 2A depicts a cross-sectional view of a semiconductor structure according to various embodiments of the subject matter disclosed herein;

FIG. 2B depicts a cross-sectional view of a semiconductor structure according to various embodiments of the subject matter disclosed herein;

FIGS. 3A-3P depict cross-section views of an example embodiment of a semiconductor structure at different stages of its manufacture;

FIGS. 4A-4P depict cross-section views of an example embodiment of a semiconductor structure at different stages of its manufacture;

FIG. 5 depicts a plan view of a method forming a semiconductor structure according to various embodiments of the subject matter disclosed herein;

FIGS. 6A and 6B depict a cross-sectional view of semiconductor structure according to various embodiments of the subject matter disclosed herein;

FIG. 7 depicts a cross-sectional view of semiconductor structure according to various embodiments of the subject matter disclosed herein; and

FIG. 8 depicts a cross-sectional view of semiconductor structure according to various embodiments of the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Counter Clockwise,” “Three-Dimensional,” etc.) may be interchangeably used with a corresponding non-capitalized version (e.g., “counter clockwise,” “three-dimensional,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein substrates may refer to a variety of materials and structures, including wafers using silicon, wafers using silicon on an insulator (SOI) such as glass, wafers of other semiconductor materials such as germanium, as well as other semiconductor materials on an insulator. In some embodiments, a substrate may include an organic material. In some embodiments, the substrates may be referred to as wafers, dies, and chips alone or in combination.

As used herein, memory may refer to various forms of semiconductor memory including both volatile memory where data is lost when power is turned off, and non-volatile memory which may retain data after power is turned off. Examples of volatile memory may include forms of random-access memory such as static random-access memory (SRAM), dynamic random-access memory (DRAM), synchronous dynamic random-access memory (SDRAM), double data rate DRAM or DDR DRAM. Examples of non-volatile memory may include flash memory devices, read only memory (ROM), programmable read only memory (PROM), electronically programmable read only memory (EPROM), electronically erasable and programmable read only memory (EEPROM), phase-change random-access memory (Phase-change RAM), ferroelectric random-access memory (FRAM), and resistive random-access memory (RRAM).

As used herein, three-dimensional memory or 3D memory may refer to any form of memory, including both volatile and non-volatile memory, containing individual elements organized in three-dimensions. For example, multiple planes of memory cells may be stacked upon each other. As used herein, vertically-stacked dynamic random-access memory (VSDRAM) may refer to a three-dimensional structure of DRAM where individual layers of DRAM elements may be stacked upon each other. In some embodiments, 3D memory may be organized that the addressing matrix is orthogonal to the memory cells. That is, in some embodiment, each of the bit line, the word line, and capacitors may extend in a different direction, such that each direction is orthogonal to each other. In some embodiments, the vertical direction, that is the direction orthogonal to the plane of the substrate, may be parallel to the bit line, while in other embodiments the word line or the capacitors may extend in the vertical direction. As used herein, bit line, word line, read line, address line, grid, array, and matrix may be used interchangeably to describe the various electrodes organized to provide a signal where two lines intersect within a larger device.

As used herein, conductors or conductive materials may refer to a variety of conductive materials, including which materials may be used alone or in combination with other materials. In some embodiments the conductor includes a semiconductor material such as, silicon (Si), germanium (Ge), gallium arsenide (GaAs), indium phosphide (InP) or any other suitable material. In some embodiments, the conductor may include a metal such as copper (Cu), tungsten (W), titanium (Ti), either alone or in combination. In some embodiments, the conductor may include a combination of materials, including oxides and nitrides. Such a listing of elements is not intended to be exhaustive, and in other embodiments, any known other type of conductive material may be used.

As used herein, dielectrics or dielectric materials may refer to non-conductive materials, and may include materials such as various semiconductor materials and the carbides, nitride and oxides thereof, such as silicon nitride (Si₃N₄) or silicon dioxide (SiO₂). Such dielectric materials may have a relatively low relative permittivity (ϵᵣ), such as less than 10 (ϵᵣ<10), or less than 20 (ϵᵣ<20), or less than 30 (ϵᵣ30), or less than 40 (ϵᵣ40), or less than 50 (ϵᵣ50), or less than 100 (ϵᵣ100) and thus be a poor conductor.

As described herein, stress engineering, also referred to as strain engineering, may modulate the properties of semiconductor materials such as electron or hole mobility and thus alter the performance of devices manufactured using the semiconductor material. A material known as a stressor may be used to impart either compressive or tensile stress into a semiconductor material such as by using the differences between the lattices of the semiconductor material and stressor. As used herein, the semiconductor material being altered may be referred to as the semiconductor channel, and may be made of any suitable semiconductor, such as silicon. The semiconductor channel may also take the form of a source channel, a drain channel, a transistor channel, a gate electrode, or may be referred to alternatively as a region.

As used herein, epitaxy refers to the process of growing a thin film of a crystalline material on an underlying material, with the orientation and type of the crystalline thin film dependent on the underlying material. A thin film grown in such a way may be referred to an epitaxial layer, or epi layer.

Disclosed herein are various embodiments of devices, systems and methods related to epitaxial shaped structures which impart stress onto channels within an integrated circuit. An epitaxial layer may be formed adjacent a semiconductor channel, and the epitaxial layer may be formed so as to match the lattice of the semiconductor material. In some embodiments, an epitaxial layer may directly stress the semiconductor channel or may be used to transfer stress from an external stressor. However, in three-dimensional transistor structures, each surface may function as a seed for epitaxial layers to grow on, with the epitaxial layers from the different seeds growing together to form a merged epitaxial layer. The merger of different seeds may introduce stacking faults and other errors within the merged epitaxial layer, such that modifying the epitaxial layer to increase the efficiency of the transferred stressor may be useful. The epitaxial layer may be formed or shaped into a structure referred to as the epi-structure to provide an efficient transfer of stress to the semiconductor channel. The shape of the epi-structure may be such that the space between the semiconductor channel and an adjacent channel, such as one providing stress, may be minimized. In some embodiments, the epi-structure may be formed as a single merged layer, while in other embodiments, the epi-structure may be formed of separated unmerged portions. In some embodiments, the epi-structure may be shaped during formation, while in other embodiments, the epi-structure may be altered after initial formation. Forming the epi-structure into an appropriate shape may provide a pathway for stress inducing materials to efficiently alter the semiconductor properties of a transistor channel.

In some embodiments, the epi-structure may be implemented in a semiconductor device formed in three-dimensions. That is, individual components such as transistors and capacitors may be formed in one or more planes, and may include various pathways and connections between the planes, such as vertical lines providing source, drain, and gate electrodes. In some embodiments, the epi-structure may be implemented in conjunction with various forms of field-effect transistors (FETs) implemented in two or three-dimensions, such as complementary field-effect transistors (CFETs), multi-bridge channel (MBC) FETs or MBCFETS, three-dimension stack FETs or 3DS-FETs, forksheet transistors, gate-all-around (GAA) FETs, and combinations thereof.

The semiconductor channel is formed of a semiconductor material such as silicon, germanium, as well as combinations thereof. In some embodiments, the semiconductor channel may take the form of a transistor channel and may extend between a source channel and a drain channel. An epi-structure may be formed between the transistor channel and a source channel or a drain channel. In some embodiments, a single epi-structure may separate the transistor channel from both the source channel and the drain channel, while in other embodiments, separate epi-structures may be formed on the source channel and the drain channel, or may be formed on only the source channel side or the drain channel side. The epi-structure may have a liner layer, such as a silicide, between the epi-structure and a conductor used to form the source channel or the drain channel. In some embodiments, the conductor may be a metal such as tungsten, copper, or aluminum, while in other embodiments, the conductor may be formed of a material such as doped semiconductor materials. A gate electrode may be formed extending along the transistor channel along a medial section between the source channel and drain channel, and may extend in a vertical direction. In some embodiments, the gate may take the form of a gate-all-around structure or GAA as part of a gate-all-around-transistor. The gate electrode may be formed of a conductive material, such as those used in the source channel or the drain channel. One or more liner layers, glue layers, and dielectric layers may be placed between transistor channel and the gate electrode, as well as between the source and drain channels.

The epi-structure may be formed as part of the creation of a FET device, including a multiple-gate FET device. An initial epitaxial structure is formed on a substrate. The epitaxial structure includes at least a first transistor channel layer between at least a first epitaxial layer and a second epitaxial layer upon the substrate. The initial epitaxial structure may then be patterned to create an epitaxial fin. The epitaxial fin may then have one or more spacer and isolation layers formed upon, which are in turned patterned to form a gate region protecting a portion of the epitaxial fin where a transistor channel is formed, and one or more trenches for the formation of the source and drain channels. The trenches are then selectively patterned to remove at least a portion of the first epitaxial layer and the second epitaxial layer with an inner spacer deposited within the cavity, while the transistor channel has the source and drain ends exposed. The epi-structure may be then formed within the trenches and contacting the exposed source and drain ends of the transistor channel. In some embodiments, the epi-structure may be formed from one or more seed structures which may merge together and be shaped into a suitable shape such as a trench, while in other embodiments, the epi-structure may be formed separately from one or more unmerged layers grown from seeds as multiple separate structures within the same trench, which may then be further shaped. The epi-structure may be shaped so as to provide an efficient transfer of stress applied from a dummy stressor to the epi-structure into the transistor channel.

After the epi-structure is formed, a dummy stressor may be deposited into the trenches of the source and drain regions and over the epi-structure. The dummy stressor may be formed using a suitable material chosen to impart a desired compressive or tensile stress. The stress may be transferred from the dummy stressor, through the epi-structure, and into the transistor channel. After the dummy stressor is formed, spacer material surrounding the transistor channel may be removed to form the gate region. Any remaining portions of the first epitaxial layer and the second epitaxial layer may also be removed. A conductive gate may be formed using one or more conductors, and may include one or more liner layers or glue layers. The dummy stressor may then be removed, and replaced by the formation of conductive source channels and conductive drain channels.

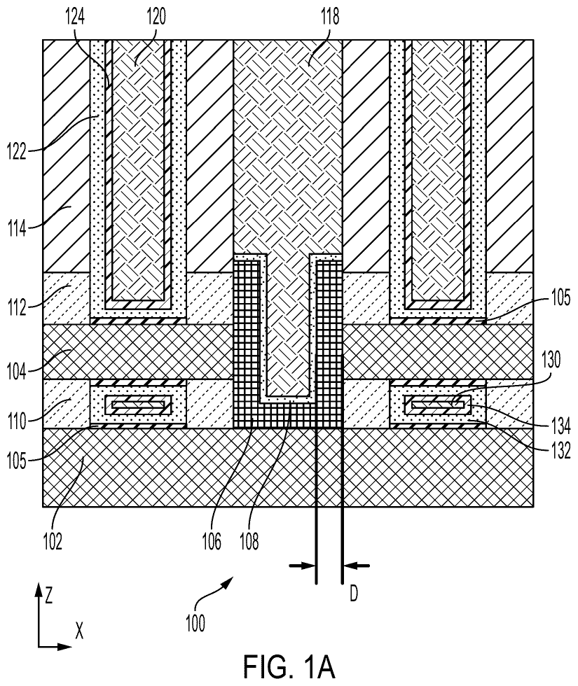

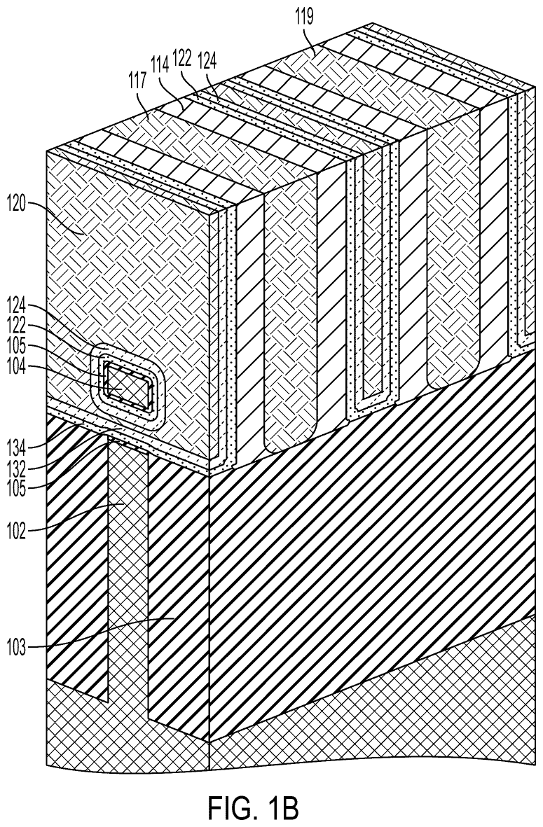

FIG. 1A depicts a cross-sectional view of an example embodiment of a first device architecture 100 while FIG. 1B depicts a perspective view of the first device architecture 100. The first device architecture 100 may form a portion of a compute device in three-dimensions, and may include a memory device, a processing device, as well as any other form of integrated circuit.

The first device architecture 100 is formed on a substrate 102, which may take the form of a semiconductor substrate, such as a silicon wafer, germanium wafer, as well glass or any other suitable substrate. A transistor channel 104 extends in a direction parallel to the substrate 102. Although FIG. 1A, and other example illustrations may show only a single example of the transistor channel 104, multiple transistor channels may be formed for each device, and multiple devices may be formed as part of a larger integrated circuit. In some embodiments, multiple transistor channels may be formed in parallel in both the horizontal and vertical directions, as part of a three-dimensional device.

The transistor channel 104 may be formed from a suitable semiconductor material, such as silicon, germanium, and combinations thereof. The transistor channel 104 may form a portion of a transistor, such as a FET, including at least one gate, source, and drain. The transistor channel 104 may be formed of a layer of semiconductor grown via an epitaxial process, and thus having crystalline orientation reflecting the substrate which the transistor channel 104 is grown upon. In some embodiments, the transistor channel 104 may have the same crystalline structure as the substrate 102, while in other embodiments the transistor channel 104 may be grown on a different substrate and transferred to the substrate 102, or an intermediate layer may be formed between the substrate 102 and the transistor channel 104 such that the transistor channel 104 reflects the crystalline structure of the intermediate layer. The transistor channel 104, as further discussed below, may be subjected to stress, and as a result may have a lower resistance and higher conductivity than an unstressed layer.

The transistor channel 104 may extend between a source channel 117 and a drain channel 119. As used herein, an electrode channel 118 may be used to refer to the source channel 117 and the drain channel 119 interchangeably. The electrode channel 118 may be formed of suitable conductive materials, such as one or more metals including tungsten, aluminum, copper, and combinations thereof. In some embodiments, the electrode channel 118 may be formed from a non-metal such as a doped semiconductor material, or conductive carbon-nanotubes. As shown in the example of FIGS. 1A and 1B, the electrode channel 118 may be formed vertically, while the transistor channel 104 may be formed in the horizontal direction, substantially orthogonal to the direction of the electrode channel 118.

An epi-structure 106 may be formed between the transistor channel 104 and the electrode channel 118. The epi-structure 106 may be formed from a thin film crystal matching the lattice of a seed surface, for example, the transistor channel 104, and may be formed from a similar material such as silicon, germanium, or a combination thereof. The epi-structure 106 may share a common crystalline structure and common crystalline orientation with surface acting as the seed, which, in some embodiments may include the transistor channel 104. Stress may be imparted into the transistor channel 104, in some embodiments, directly by the formation of epi-structure 106, where the materials properties as well as differences such as lattice mismatch may induce strain in the transistor channel 104, while in some embodiments, stress may be imparted indirectly with the epi-structure 106 providing a structure to transfer stress to the transistor channel 104 from an external stressor. However, in a three-dimensional transistor structure, the epi-structure 106 may be grown from multiple different surfaces acting as the seed surface, with the merger of multiple different seeds forming the epi-structure 106. The merger of multiple seeds may introduce stacking faults and other errors within a merged crystalline structure which may reduce efficiency with which stress from an epitaxial layer may either directly induce or indirectly transmit. As such, the epi-structure 106 may be shaped to more efficiently transfer stress imparted from a dummy stressor on to the epi-structure 106 to the transistor channel 104. An epi-structure 106 which is formed from two or more seeds merging together may be referred to as merged, as well as unitary or contiguous. In contrast, an epi-structure 106 which is formed by two or more seeds which are not merged may be referred to as unmerged or separated portions.

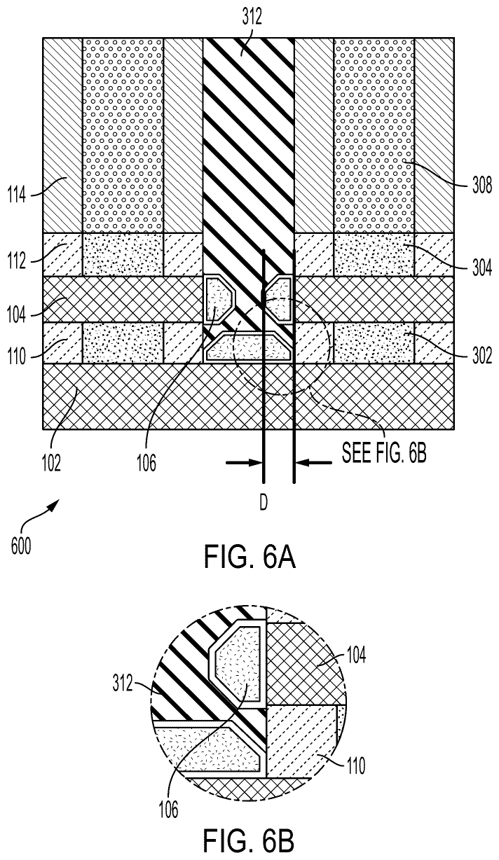

In some embodiments, the efficiency of stress transfer by the epi-structure 106 may at least be partially based on the distance D between the transistor channel 104 and a stressor material. In the example embodiment of FIG. 1A, the distance D corresponds to the thickness of the epi-structure 106 between the transistor channel 104 and a first barrier layer 108 between the epi-structure 106 and the electrode channel 118. However, as discussed further below with respect to FIGS. 6-8, the shape of the epi-structure 106 may vary such that the distance between the transistor channel 104 and a stressor material may be less than the thickness of a layer used to form the epi-structure 106.

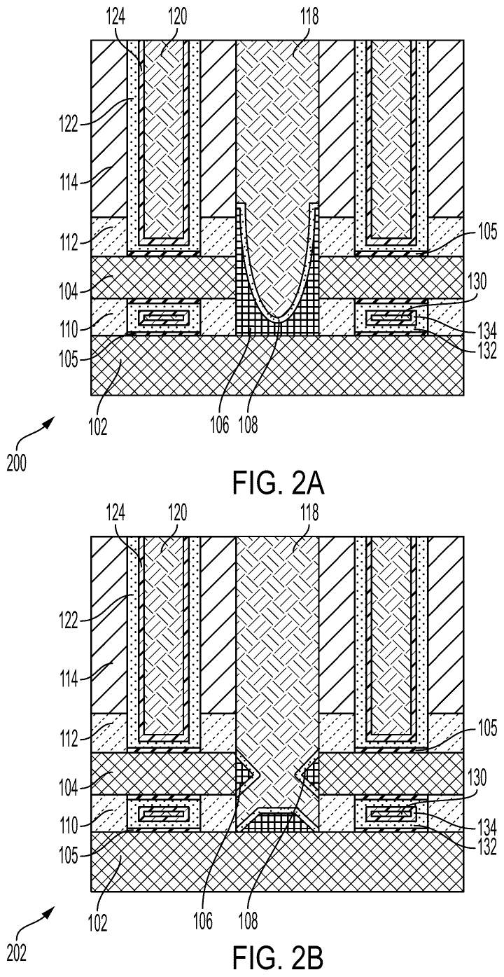

In the example embodiment of FIG. 1A, the epi-structure 106 takes the form of a U-shaped structure conforming to the trench walls defining the electrode channel 118. However, the epi-structure 106 as shown in FIG. 1A is merely an example, and the epi-structure 106 may be shaped in multiple ways to efficiently transfer stress onto the transistor channel 104 from a stressor. For example, while in the example embodiment of FIG. 1A, the epi-structure 106 may take the form of a U-shaped structure, in other embodiments the epi-structure 106 may take the form of a surface layer having a parabolic shaped trench formed by etching, or one or more polygon shapes which may be separated from one another. The shape of the epi-structure 106 may be further influenced by manufacturing considerations such that the U-shape, a parabolic shape, as well as separated polygon shapes as shown herein may be considered approximate shapes, and the shapes may thus vary. Additionally, as the epi-structure 106 may be subjected to stress from a stressor, a semiconductor material used to form the epi-structure 106 may be under stress along with the transistor channel 104 and may have a lower resistance than an unstressed layer of the same material. In some embodiments, such as in FIG. 1A, the distance D may be approximately constant in the Z-direction, while in other embodiments such as FIG. 2A and FIG. 2B, the distance D may vary. For example, the distance D in FIG. 2A may be considered inversely related to the distance from the substrate 102, as the epi-structure 106 may be formed into a parabolic shape having a shape which is concave with respect to the electrode channel 118. The distance D may also be concave with respect to the electrode channel 118, such as in the example of FIG. 2B, where the trapezoidal shape of the epi-structure 106 extends outward into the electrode channel 118. As used herein, convex may refer to a shape extending outward from a surface, while concave may refer to a shape extending inward from a surface.

The first barrier layer 108 may be formed between the epi-structure 106 and the electrode channel 118. The first barrier layer 108 may be formed of a suitable material to enable a conductive connection between a semiconductor material in the epi-structure 106 and the conductive material of the electrode channel 118, as well as to act as an adhesive layer to form a mechanical bond. In some embodiments, the first barrier layer 108 may be formed of a silicide material such as nickel silicide (NiSi), cobalt silicide (CoSi), or tungsten disilicide (WSi₂). The first barrier layer 108 may also prevent migration of conductive material of the electrode channel 118 into the transistor channel 104. The shape of the epi-structure 106 may be formed in part so as to provide sufficient spacing between the transistor channel 104 and the first barrier layer 108 during the formation of the first barrier layer 108 such that the transistor channel 104 may be isolated from the formation process.

The transistor channel 104 may be vertically surrounded by one or more gate electrodes, such as a first gate electrode 120 on top of the transistor channel 104 and a second gate electrode 130 between the transistor channel 104 and the substrate 102. In some embodiments, such as shown in FIG. 1B, the first gate electrode 120 and the second gate electrode 130 may be the same channel, as part of a gate-all-around structure surrounding the transistor channel 104 along top, bottom and sides of the transistor channel 104. The material of the first gate electrode 120 and the second gate electrode 130 includes at least one conductive material, such as one or more metals including tungsten, aluminum, copper, and combinations thereof. In some embodiments, the first gate electrode 120 and the second gate electrode 130 may be formed from a non-metal such as a doped semiconductor material, or conductive carbon-nanotubes. In some embodiments, the first gate electrode 120 and the second gate electrode 130 may be formed of the same material, while in other embodiments the first gate electrode 120 and the second gate electrode 130 may be formed of different materials. In some embodiments, the first gate electrode 120 and the second gate electrode 130 may be formed of the same conductive materials as the electrode channel 118, while in other embodiments, the first gate electrode 120 and the second gate electrode 130 may be formed of different materials from the electrode channel 118. The first gate electrode 120 and the second gate electrode 130 may be located at a medial location between a source end of the transistor channel 104 and a drain end of the transistor channel 104. The first gate electrode 120 and the second gate electrode 130 may provide a gate voltage to the transistor channel 104, providing a field-effect to alter the conductivity of the transistor channel 104. Thus, in some embodiments, the transistor channel 104 may form a field effect transistor. Furthermore, in some embodiments, the first gate electrode 120 and the second gate electrode 130 may be part of a gate-all-around transistor structure, such that both the first gate electrode 120 and the second gate electrode 130 are part of the same electrode structure. See, for example, FIG. 1B where the first gate electrode 120 wraps around the transistor channel 104 such that the second gate electrode 130 may be considered a portion of the first gate electrode 120.

A first dielectric material 114 may be formed above the transistor channel 104 and be spaced between the first gate electrode 120 and the electrode channel 118. The first dielectric material 114 may be any suitable dielectric material, including nitrides, carbides and oxides of semiconductor materials, and may consist of silicon oxide, silicon nitride, or other similar materials such as gallium nitride, gallium oxide, and so forth. A first inner spacer 110 may be formed between the transistor channel 104 and the substrate 102 vertically, and the second gate electrode 130 and the electrode channel 118 horizontally. A second inner spacer 112 may be formed between the transistor channel 104 and the first dielectric material 114 vertically and between the first gate electrode 120 and the electrode channel 118 horizontally. The material of the first inner spacer 110 and the second inner spacer 112 may be any suitable dielectric material, including nitrides, carbides and oxides of semiconductor materials, and may consist of silicon oxide, silicon nitride, or other similar materials such as gallium nitride, gallium oxide, and so forth. In some embodiments, the material of the first inner spacer 110 and the second inner spacer 112 may be the same material, while in other embodiments the material of the first inner spacer 110 and the second inner spacer 112 may differ.

In some embodiments, a transistor liner layer 105 may be between the transistor channel 104 and the first gate electrode 120 or second gate electrode 130 to provide support and protection for the transistor channel 104. A portion of the transistor liner layer 105 may also extend between the substrate 102 and the second gate electrode 130. The transistor liner layer 105 may be formed of a suitable dielectric material including nitrides, carbides and oxides of semiconductor materials, and may consist of silicon oxide, silicon nitride, or other similar materials such as gallium nitride, gallium oxide, and so forth. In some embodiments, the transistor liner layer 105 may be formed of a native oxide.

Between the transistor channel 104 and the first gate electrode 120 may be a first liner layer 124 and a first gate dielectric 122. A second liner layer 134 and a second gate dielectric 132 may be formed between the transistor channel 104 and the second gate electrode 130. The first liner layer 124 and the second liner layer 134 may be formed of a suitable material compatible with the first dielectric material 114, the transistor channel 104, and the substrate 102, and may consist of an oxide, nitride, or carbide of a semiconductor material, for example silicon dioxide (SiO₂). Additionally, or alternatively, in some embodiments, the first liner layer 124 and the second liner layer 134 may include a material such as a dipole and may be used to alter the potential difference of the gate electrode and the transistor channel 104. The first gate dielectric 122 and the second gate dielectric 132 may be formed from a suitable dielectric material, and may be a high-K dielectric material, for example hafnium oxide (HfO₂). In some embodiments, the first gate dielectric 122 and the second gate dielectric 132 may be part of the same layer, such as in a gate-all-around configuration as shown in FIG. 1B. In other embodiments, the first gate dielectric 122 and the second gate dielectric 132 may be separate layers. In some embodiments, the first liner layer 124 and the second liner layer 134 may be part of the same layer, such as in a gate-all-around configuration as shown in FIG. 1B. In other embodiments, the first liner layer 124 and the second liner layer 134 may be separate layers. Furthermore, in some embodiments, a portion of the transistor liner layer 105 may be formed between the second gate dielectric 132 and the substrate 102.

FIG. 2A depicts a cross-sectional view of an example embodiment of a second device architecture 200, which differs from the first device architecture 100 by the shape of the epi-structure 106. In the first device architecture 100, the epi-structure 106 is formed in a rectangular U-shape with walls covering the channel walls, while the electrode channel 118 extends in a smaller trench through the epi-structure 106. In the second device architecture 200, the epi-structure 106 is formed into a conic section, such as a parabola or semi-circle. The epi-structure 106 may be formed from the epi growths from three discontinuous surfaces being grown into a merged structure, and may remove some or all of the material, such as via an etching process, so that the distance between a dummy stressor and the transistor channel 104 is minimized. The electrode channel 118 may form a complimentary shape to the epi-structure 106. The relative steepness of the conic section as well as the focal distance may be chosen so that the width of the epi-structure 106 may be minimized. As such, the distance between a dummy stressor and the transistor channel 104 may be reduced, so that stress may be more efficiently transferred to the transistor channel 104.

FIG. 2B depicts a cross-sectional view of an example embodiment of a third device architecture 202, which differs from the first device architecture 100 and the second device architecture 200 by the shape of the epi-structure 106. In the first device architecture 100 and the second device architecture 200, the epi-structure 106 is a contiguous and merged structure across the width of the electrode channel 118. However, in the third device architecture 202, the epi-structure 106 may be formed in multiple separated and unmerged portions. In the example embodiment of FIG. 2B, the separated and unmerged portions of the epi-structure 106 are shown having roughly triangular or trapezoidal cross-sections. However, in other embodiments, the separated and unmerged portions of the epi-structure 106 may have any suitable shape, including circular, rectangular, elliptical, and conic shapes. The shape of the epi-structure 106 may be chosen such that the distance between a dummy stressor and the transistor channel 104 may be reduced, so that stress may be more efficiently transferred to the transistor channel 104.

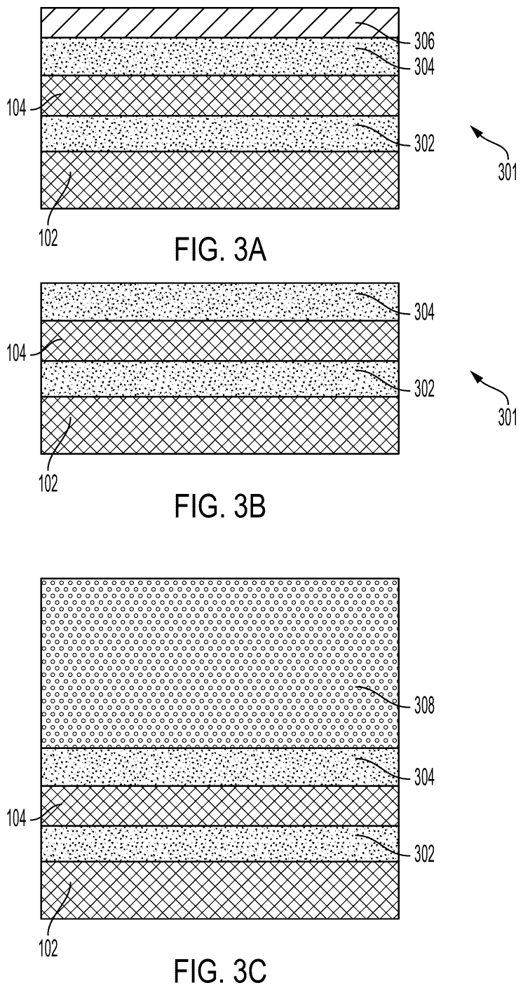

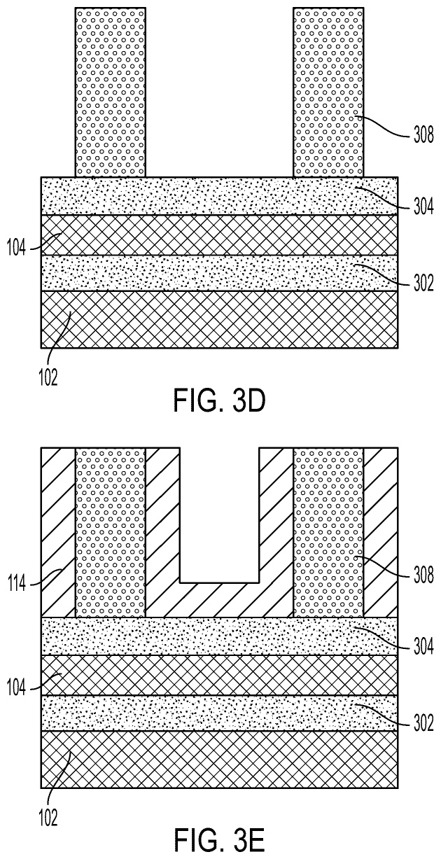

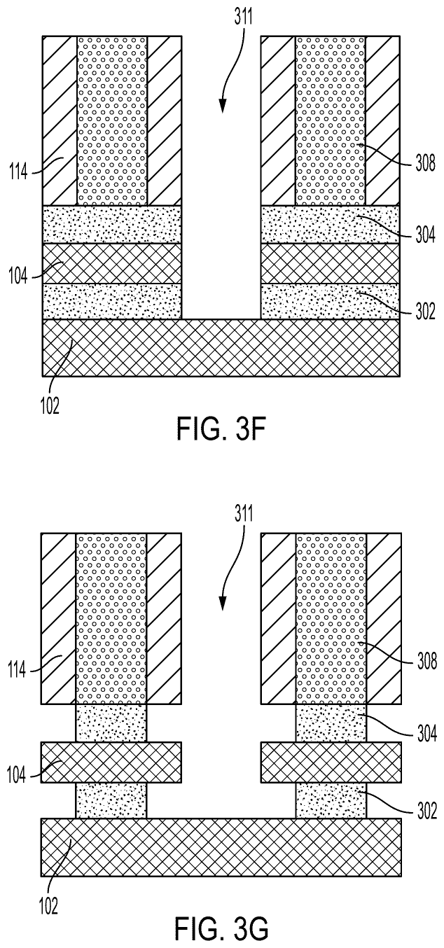

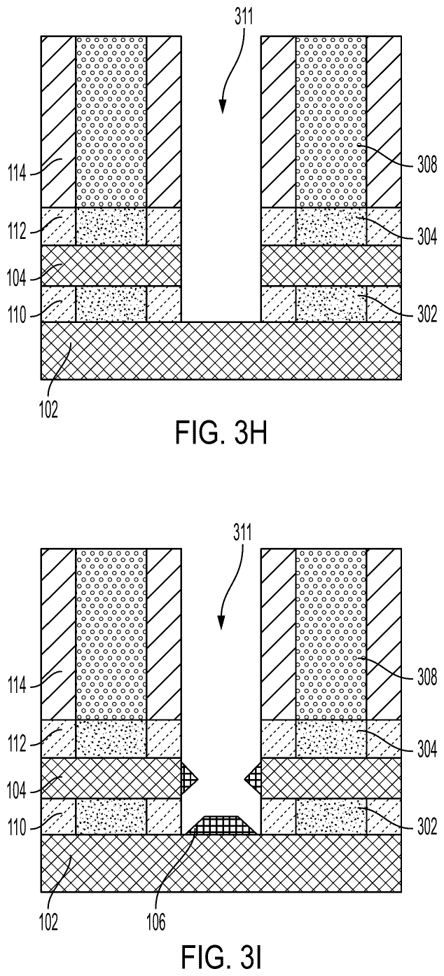

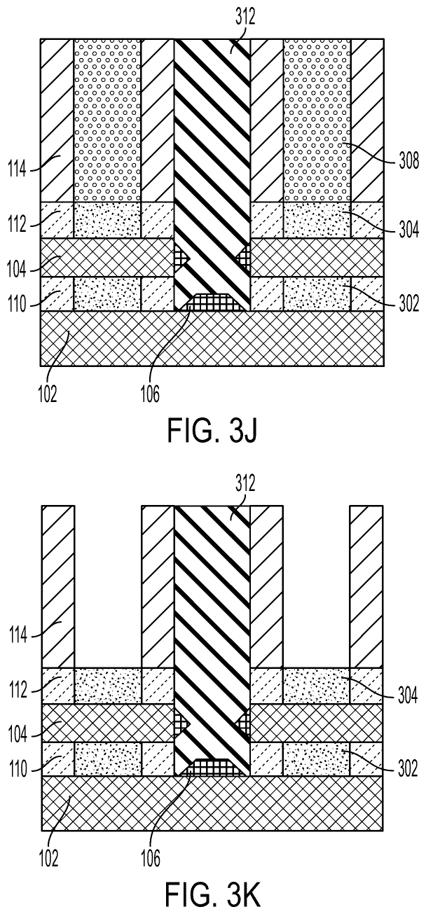

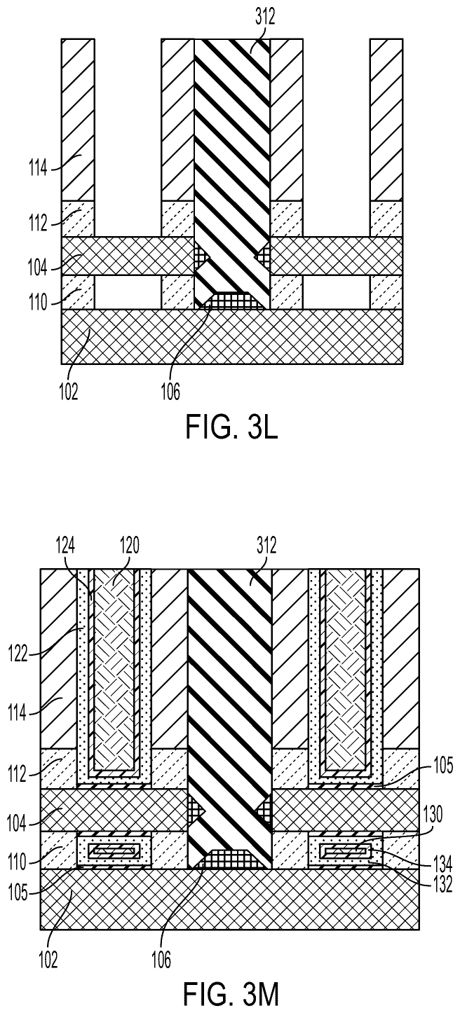

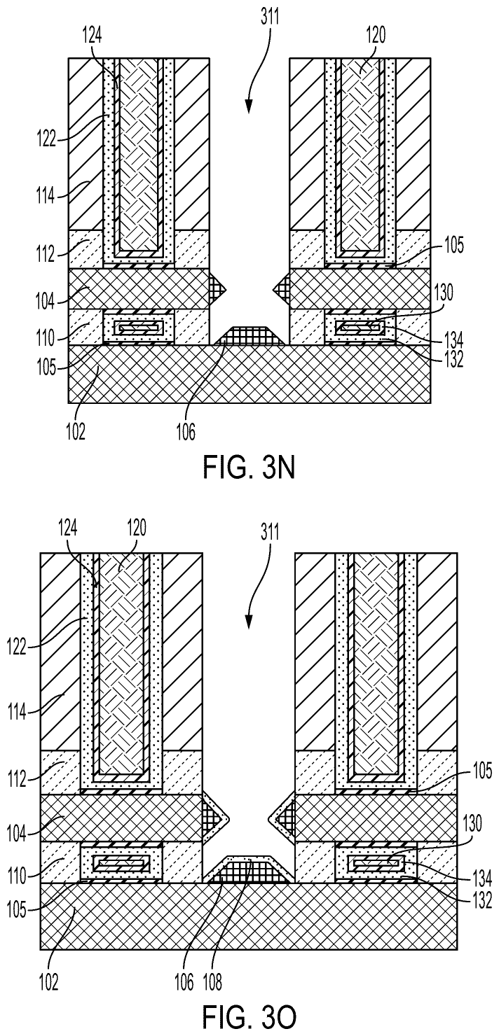

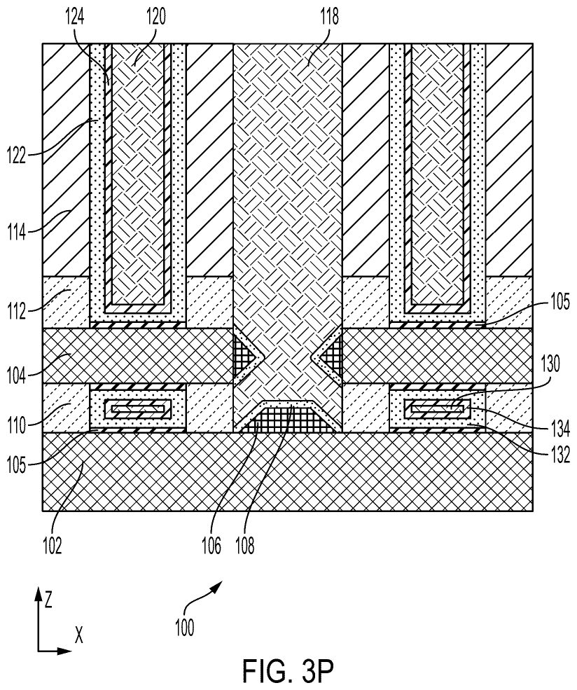

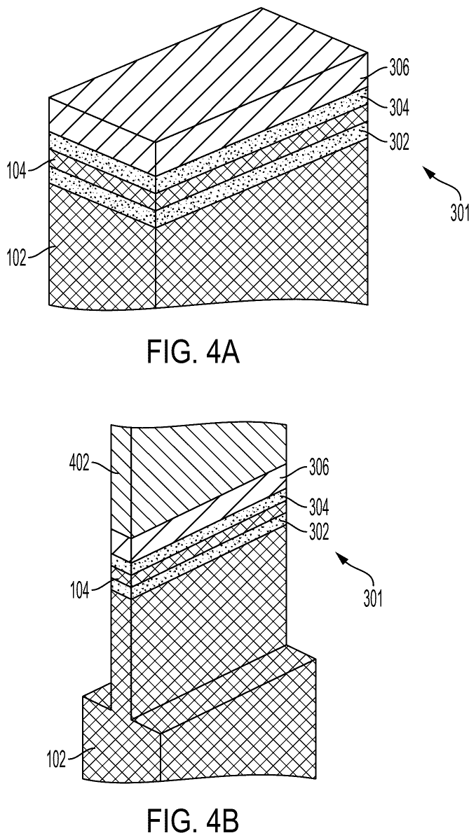

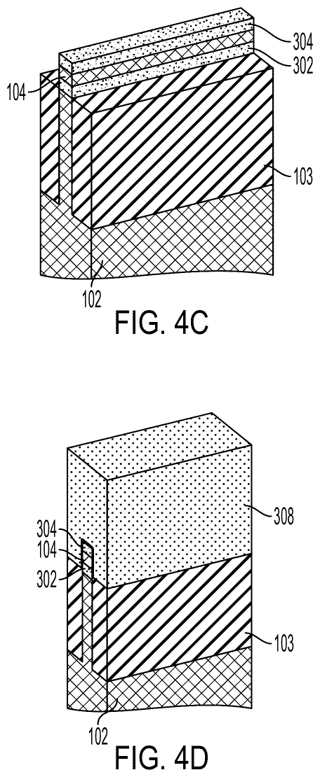

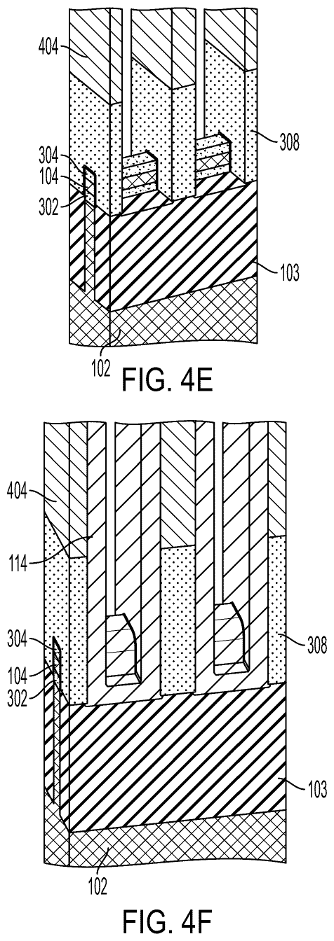

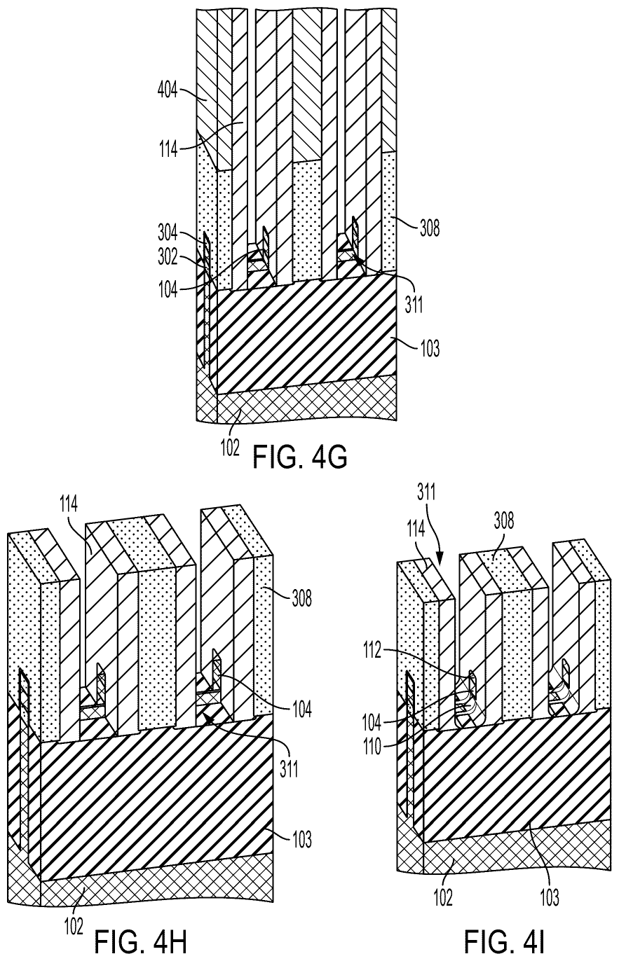

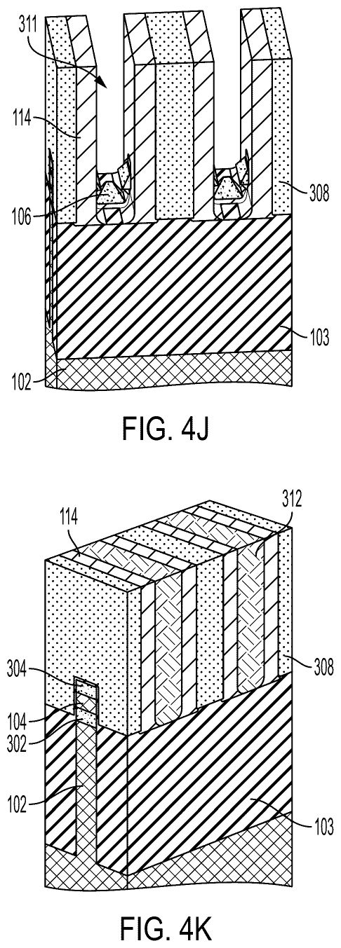

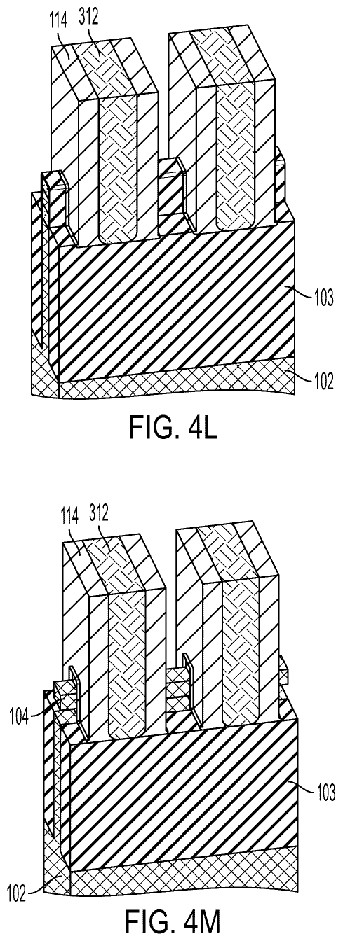

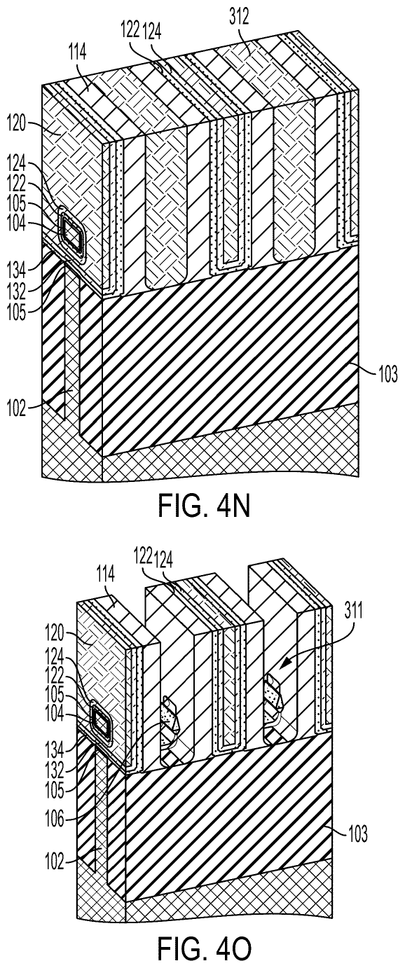

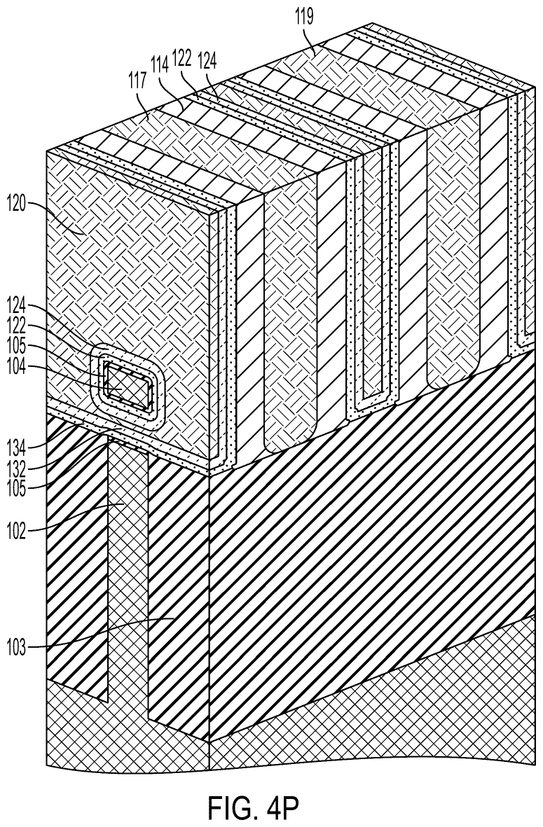

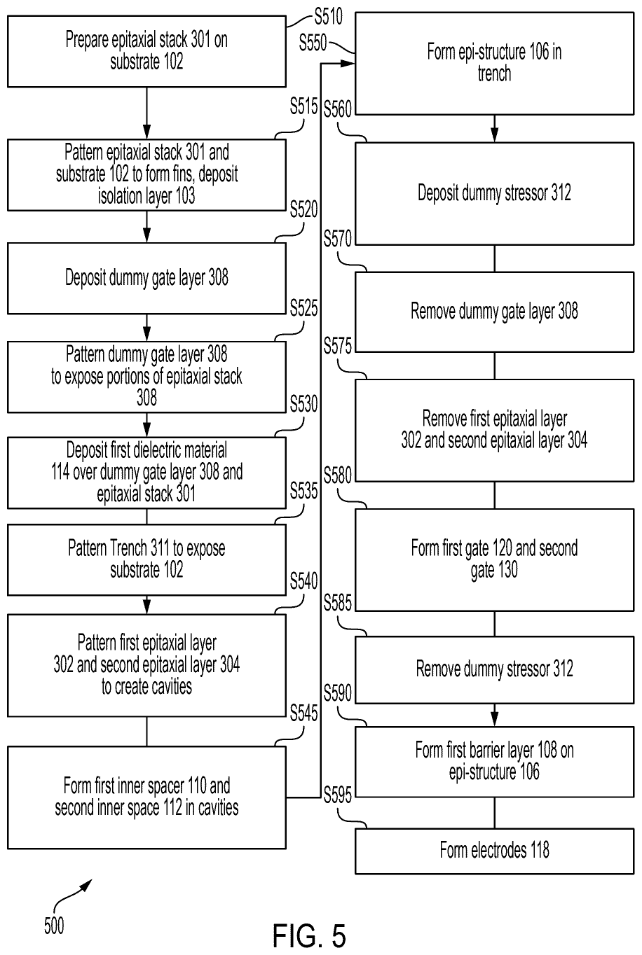

FIGS. 3A-3P and FIGS. 4A-4P depict an illustrative embodiment of a process of forming a device architecture such as the first device architecture 100, or any other device architecture shown herein. FIGS. 3A-3P also provide a cross-sectional view, while FIG. 4A-4P provides a perspective view. FIG. 5 depicts an example embodiment of a process 500 for forming a device architecture corresponding to the illustrative embodiment of FIGS. 3A-3P and FIGS. 4A-4P.

FIG. 3A and FIG. 4A depict S510 in the process of FIG. 5, where an epitaxial stack 301 is prepared on substrate 102. Substrate 102 may be any suitable semiconductor substrate, such as silicon, germanium, or a combination thereof, and may take the form of a wafer, die, or a semiconductor layer formed upon an insulative substrate such as glass. The epitaxial stack 301 may have a first epitaxial layer 302 formed directly on the substrate 102, with the semiconductor material for the transistor channel 104 formed on the first epitaxial layer 302. A second epitaxial layer 304 may be formed on top of the semiconductor material for the transistor channel 104. Finally, a capping layer 306 may be formed on top of the second epitaxial layer 304. The epitaxial layers may be formed by any suitable process, including atomic layer deposition (ALD), chemical vapor deposition (CVD), physical vapor deposition (PVD), as well as methods such as molecular beam epitaxy (MBE), alone or in combination. The semiconductor material for the transistor channel 104 may be a single semiconductor material such as silicon or germanium, and may have a thickness of 5-15 nm, or may be larger in the range of 15-100 nm, or may be smaller in the range of 1-5 nm. The first epitaxial layer 302 may be formed by a mixed semiconductor, such as a combination of silicon and germanium, and may be in the range of 15-25% mol of germanium, although the concentration of germanium may be larger such as in the range of 25%-75% mol, or may be smaller such as in the range of 1%-15% mol. The thickness of the first epitaxial layer 302 may be the same as the transistor channel 104 and may have a thickness of 5-15 nm, or may be larger in the range of 15-100 nm, or may be smaller in the range of 1-5 nm. The second epitaxial layer 304 may be formed similar to the first epitaxial layer 302. In some embodiments, the thickness of the first epitaxial layer 302 and the second epitaxial layer 304 may be the same, while in other embodiments, the thickness may differ. The first epitaxial layer 302, the semiconductor material of the transistor channel 104, and the second epitaxial layer 304 are grown epitaxially, and have the same crystalline orientation and type as the substrate 102. Alternatively, in some embodiments, the epitaxial stack 301 may be grown on a different substrate and transferred to the substrate 102, or formed on an intermediate crystalline structure between the epitaxial stack 301 and the substrate 102, such that the epitaxial stack 301 may differ in the lattice structure from the substrate 102.

The capping layer 306 formed on the second epitaxial layer 304 may, in some embodiments, be used to provide protection for the epitaxial stack 301. For example, in some embodiments, the capping layer 306 may be formed of a nitride material such as silicon nitride, or an oxide material such as silicon oxide. In some embodiments, the thickness of the capping layer 306 may be 10-20 nm, while in other embodiments the thickness may be smaller such as in the range of 1-10 nm, or may be larger, such as in the range of 20-100 nm or 100-1,000 nm.

FIG. 4B depicts S515 in the process of FIG. 5, where the epitaxial stack 301 is patterned to form a fin shaped structure. The patterning may be implemented using any suitable semiconductor process, and may include techniques such as etching, including both wet-etch processes using chemicals and dry-etch processes using reactive plasma, as well as lithography, lasers, and a combination of these methods and any other suitable methods known in the art. A masking step may also be performed, such as applying a first photoresist 402 over the capping layer 306 prior to forming the fin. In some embodiments, the patterning may remove a portion of the substrate 102, and a surface trench isolation layer 103 may be formed between adjacent fins. The surface trench isolation layer 103 may be formed using an appropriate semiconductor technique such as ALD, CVD, PVD, and may deposit a dielectric material such as a nitride, oxide, or carbide compatible with the substrate 102.

FIG. 3B and FIG. 4C depict the aftermath of S515 in the process of FIG. 5, after the surface trench isolation layer 103 has been deposited, with the first photoresist 402 and the capping layer 306 being removed. The first photoresist 402 may be removed separately from the capping layer 306, for example, by use of a suitable solvent. The capping layer 306 may then be removed by an appropriate process, for example, a selective etch. Additionally, or alternatively, a planarization process, such as a chemical-mechanical polish (CMP) may be used to remove the photoresist 402.

FIG. 3C and FIG. 4D depict S520 in the process of FIG. 5, where a dummy gate layer 308 is deposited over the epitaxial stack 301. The dummy gate layer 308 may be formed from any suitable material compatible with the chemistry of the substrate 102, and may be specifically chosen such that the selective patterning may be performed between the gate, dielectric, and electrode regions. For example, the dummy gate layer 308 may be a polysilicon material having a different etch susceptibility than a nitride or oxide layer, and may enable a selective removal process. The dummy gate layer 308 may be deposited using an approximate semiconductor technique, such as CVD, PVD or ALD.

FIG. 3D and FIG. 4E depict S525 in the process of FIG. 5, where the dummy gate layer 308 is patterned to expose the epitaxial stack 301 in the spacer and electrode regions. The patterning may be implemented using any suitable semiconductor process, and may include techniques such as etching, including both wet-etch processes using chemicals and dry-etch processes using reactive plasma, as well as lithography, lasers, and a combination of these methods and any other suitable methods known in the art. A masking step may also be performed, such as applying a second photoresist 404 over the dummy gate layer 308 prior to conducting an etch.

FIG. 3E and FIG. 4F depict S530 in the process of FIG. 5, where the first dielectric material 114 is deposited to form a gate spacer. The first dielectric material 114 may be any suitable dielectric material, including nitrides, carbides and oxides of semiconductor materials, and may consist of silicon nitride, silicon oxide, or other similar materials such as gallium nitride, gallium oxide, and so forth. The first dielectric material 114 may be deposited using any appropriate technique such as CVD, PVD, and ALD.

FIG. 3F and FIG. 4G depict S535 in the process of FIG. 5, where a trench 311 is formed through the first dielectric material 114 and the epitaxial stack 301 in the source and drain regions. The trench 311 may be formed using any suitable semiconductor process, and may include techniques such as etching, including both wet-etch processes using chemicals and dry-etch processes using reactive plasma, as well as lithography, lasers, and a combination of these methods and any other suitable methods known in the art. The trench 311 may extend down to reach the substrate 102 and the surface trench isolation layer 103. In some embodiments, when a photoresist such as the second photoresist 404 was used during the patterning process, the photoresist may then be removed. For example, in some embodiments the photoresist may be removed using a suitable solvent to dissolve the photoresist, while in other embodiments, the photoresist may be removed during a planarization process, such as a CMP.

FIG. 3G and FIG. 4H depict S540 in the process of FIG. 5, where a portion of the wall of the trench 311, is removed, with portions of the first epitaxial layer 302 and second epitaxial layer 304 removed. The removal may be done using a suitable lateral process, such as a selective etch, and may have a sufficient depth to extend through the first dielectric material 114. The removal process may reduce stress at the edge of the transistor channel 104, while increasing tensile stress experienced by the transistor channel 104 away from the edges. The removal process may form one or more cavities within the first dielectric material 114 suitable for forming a spacer.

FIG. 3H and FIG. 4I depict S545 in the process of FIG. 5, where the first inner spacer 110 and the second inner spacer 112 are formed within the cavities created by the removal of portions of the first epitaxial layer 302 and the second epitaxial layer 304. The first inner spacer 110 and the second inner spacer 112 may be formed of a dielectric material, such as a nitride, oxide, or carbide, such as silicon nitride. The first inner spacer 110 and the second inner spacer 112 may be formed of the same material, or may differ in material composition. The first inner spacer 110 and the second inner spacer 112 may be thus formed in the same process, or may be formed in differing processes. Any suitable deposition technique may be used, including conformal processes such as ALD, as well as CVD or PVD.

FIG. 3I and FIG. 4J depict S550 in the process of FIG. 5, where the epi-structure 106 is formed within the trench 311. The epi-structure 106 may be formed using one or more suitable epitaxial processes, such as ALD, CVD, PVD, where an appropriate epitaxial material may be formed, such as silicon or germanium, and nitrides and oxides thereof. The epi-structure 106 may be grown such that surfaces in contact with the transistor channel 104 thus have the same crystalline orientation and type as the surface of the transistor channel 104 the epi-structure 106 is grown from, and surfaces in contact with the substrate 102 may have the same crystalline orientation and type as the surface of the substrate 102 the epi-structure 106 may be grown from. In some embodiments, the epi-structure 106 may be used to impart stress directly on to the transistor channel 104. However, in some embodiments, the epi-structure 106 may be grown on multiple surfaces, and each of the surfaces may act as seed layers and which may merge together and may introduce errors such as stacking faults and other defects into the epi-structure 106. By shaping the epi-structure 106, stress transfer may more efficiently transfer stress from a stressor material by reducing or eliminating the effects of stacking faults and other defects when transferring stress.

The epi-structure 106 may be shaped to provide a desired shaped structure to transfer stress more efficiently. As discussed further herein, the epi-structure 106 may be shaped to reduce the distance between a material added as the stressor and the transistor channel 104. A decrease of distance may increase the efficiency of the transmitted stress to the transistor channel 104. In addition, the epi-structure 106 may have the thickness, shape and material chosen at least in part so the formation of the first barrier layer 108 does not alter the transistor channel 104. For example, when the first barrier layer 108 is a silicide layer formed using a reactive CVD process, the epi-structure 106 may be shaped such that a silicide reaction may be unable to affect material within the transistor channel 104. The epi-structure 106 thus may be shaped to minimize distance between the transistor channel 104 and the dummy stressor, while also providing sufficient spacing to avoid siliconization of the transistor channel 104. Such shapes may include unitary structures where part of the epi-structure 106 is removed, as well as more complex shaped structures such as polygons, conic sections, etc.

The epi-structure 106 may be formed either as a merged structure across the trench 311 or may be formed of unmerged separate portions as in FIG. 4J where the epi-structure 106 is in the form of multiple unconnected trapezoids. In some embodiments, the epi-structure 106 may be formed by first forming an epitaxial material within the trench 311, and then removing a portion of the epitaxial material, while in other embodiments, the epitaxial material may be formed using a process to grow the epitaxial material into an appropriate shape. Additionally, some embodiments may use a combination of removal processes and growth processes to create a desired shape. In some embodiments, the formation process may be chosen so that epitaxial material will form on only the exposed portions of the transistor channel 104, while in other embodiments, the deposition process will form epitaxial material on any exposed surface. In some embodiments, the epitaxial material may be first formed into multiple separate shapes, and then further shaped, for example using an etch. In some embodiments, the epi-structure 106 may be formed so as to minimize the space between the transistor channel 104 and the trench 311.

FIG. 3J and FIG. 4K depict S560 in the process of FIG. 5, where a dummy stressor 312 is deposited in the trench 311. The dummy stressor 312 may be formed of an appropriate material, including semiconductor materials, dielectrics, metals, etc. with an intrinsic stress, and may be further chosen in order to provide a desired stress on to the transistor channel 104. As the stress transfer needs to pass through the epi structure 106, it is important to minimize the epi structure 106 volume; the distance between the dummy stressor 312 and the transistor channel 104 must be minimized. In some embodiments, the dummy stressor 312 may be chosen to provide stress via a lattice mismatch from the epi-structure 106, while in other embodiments, the dummy stressor 312 may provide an intrinsic stress. The dummy stressor 312 may be deposited using an appropriate technique such as CVD, PVD, ALD, and may be combined with additional processing steps such as masking, planarization, or patterning to remove excessive material. The dummy stressor 312 may be chosen to impart a desired stress on the transistor channel 104, with the epi-structure 106 increasing the efficiency of the stress transfer from the dummy stressor 312 to the transistor channel 104. For example, in some embodiments, the stress transferred to the transistor channel 104 may be in the range of 0.75-1 GPa, while in other embodiments, the transferred stress may be greater than 1 GPa, in the range of 1.5 to 3 GPa or may be less than 0.75-1 GPa, for example in the range of 0.25-0.75 GPa. In some embodiments, the transferred stress may produce a tensile stress within the transistor channel 104, while in other embodiments the transferred stress may result in a compressive stress within the transistor channel 104, and thus may provide a decrease in the resistance within the transistor channel 104.

As the epi-structure 106 may increase the efficiency of the stress transferred into the transistor channel 104 from the dummy stressor 312, so the stress present within the transistor channel 104 may thus be increased. The increase in stress within the transistor channel 104 may thus reduce the resistance of the transistor channel 104, and improve the overall performance of the transistor.

FIG. 3K and FIG. 4L depict S570 in the process of FIG. 5, where the dummy gate layer 308 is removed. The removal may be done using a suitable semiconductor process, such as a selective etching process. In some embodiments, the dummy gate layer 308 may be formed of material having a different etch sensitivity than the dummy stressor 312 or the first dielectric material 114.

FIG. 3L and FIG. 4M depict S575 in the process of FIG. 5, where remaining portions of the first epitaxial layer 302 and the second epitaxial layer 304 in the gate region are removed. The removal may be done using an approximate semiconductor process, such as a selective etch, including wet or dry etch, and may include further masking or photolithography steps.

FIG. 3M and FIG. 4N depict S580 in the process of FIG. 5, where the gate region is formed including the transistor liner layer 105, the first liner layer 124, the second liner layer 134, the first gate dielectric 122, the second gate dielectric 132, the first gate electrode 120 and the second gate electrode 130. The transistor liner layer 105 may be formed of a suitable material compatible with the material of the first inner spacer 110 and the second inner spacer 112, the transistor channel 104, and the substrate 102, and may consist of an oxide, nitride, or carbide of a semiconductor material, for example silicon dioxide (SiO2). The first gate dielectric 122 and the second gate dielectric 132 may be formed from a suitable dielectric material, and may be a high-K dielectric material, for example hafnium oxide (HfO₂). The first liner layer 124 and the second liner layer 134 may be formed from a suitable dielectric material, or may, in some embodiments include a dipole material. The first gate electrode 120 and the second gate electrode 130 may be formed of a suitable conductive material, such as a metal like tungsten or a doped carbon nanotube. The various layers of the gate region may thus be formed using one or more suitable semiconductor techniques including PVD, CVD, and ALD. In addition, one or more patterning processes such as photolithography, one or more planarization processes such as CMP, or a combination thereof may be used to trim excess portions of the gate region.

In some embodiments, the first gate dielectric 122 and the second gate dielectric 132 may be formed at the same time by the formation of the same dielectric material, the first gate dielectric layer 122 thus may refer to the portion of the dielectric material above the transistor channel 104 in FIG. 3M, while the second gate dielectric 132 may refer to the portion of the material below the transistor channel 104 in FIG. 3M. Similarly, the first liner layer 124 and the second liner layer 134 may be formed at the same time by the formation of the same material, the first liner layer 124 thus may refer to the portion of the material above the transistor channel 104 in FIG. 3M, while the second liner layer 134 refers to the portion of the material below the transistor channel 104 and on top of portion of the transistor liner layer 105 over the substrate 102 in FIG. 3M.

In some embodiments, the formation of the gate region may lock in the stress in the transistor channel 104 imparted by the dummy stressor 312 such that the dummy stressor 312 may be removed without impacting the stress within the transistor channel 104. The stress received by transistor channel 104 from the dummy stressor 312 and transmitted via the epi-structure 106 may remain after the removal of the dummy stressor 312.

FIG. 3N and FIG. 4O depict S585 in the process of FIG. 5, where the dummy stressor 312 is removed. The dummy stressor 312 may be removed by any suitable techniques such as etching, including both wet-etch processes using chemicals and dry-etch processes using reactive plasma, as well as lithography, lasers, and a combination of these methods and any other suitable methods known in the art. The removal of the dummy stressor 312 will expose the epi-structure 106. The stress imparted by the dummy stressor 312 on the transistor channel 104 may remain, however, as the gate region may keep the stress transmitted via the dummy stressor 312 into the transistor channel 104 into place.

FIG. 3O depicts S590 in the process of FIG. 5, where the first barrier layer 108 is formed on the epi-structure 106. The first barrier layer 108 may be formed of a suitable material to enable a connection between a semiconductor material in the epi-structure 106 and the conductive material of the electrode channel 118. In some embodiments, the first barrier layer 108 may be formed of a silicide material such as nickel silicide (NiSi), cobalt silicide (CoSi), or tungsten disilicide (WSi₂). The first barrier layer 108 may be formed by any appropriate technique, including PVD, CVD, and ALD. The first barrier layer 108 may also provide a barrier for material migration for later deposited conductive materials to migrate into the transistor channel 104. The thickness and shape of the epi-structure 106 may be altered based on the material and process used to form the first barrier layer 108. For example, when the first barrier layer 108 is a silicide material, semiconductor materials such as silicon used within the transistor channel 104 may react to the silicide formation process. As such, the epi-structure 106 may be chosen such that the first barrier layer 108 is able to form a good contact layer without altering the transistor channel 104.

FIG. 3P and FIG. 4P depict S595 in the process of FIG. 5, where the electrode channel 118 is formed in the trench 311 over the first barrier layer 108 and the epi-structure 106. The electrode channel 118 may be formed from a conductor such as a metal like tungsten, as well as aluminum, or non-metal conductors such as doped carbon nanotubes. As such, the electrode channel 118 may be formed by the appropriate semiconductor process such as PVD, CVD, and ALD. The material used in the electrode channel 118 may be chosen such that the material of the first barrier layer 108 may form a favorable contact between the electrode channel 118 and the transistor channel 104. In some embodiments, a patterning step such as forming a protective mask may be performed prior to the formation of the electrode channel 118 to allow selective formation of the conductor in the electrode channel 118. In other embodiments, one or more patterning processes such as lithography, one or more planarization processes such as CMP, and a combination thereof may be used after the formation of the conductor in the electrode channel 118 to remove excess conductor.

FIGS. 6A and 6B depict an alternative version of S560 shown in FIG. 3J, showing a first intermediate structure 600 where the epi-structure 106 may be formed as a separated structure where the epi growth from the separate seed portions may be unmerged. In FIG. 6A, the epi-structure 106 is formed into trapezoidal shapes in the cross-sectional view. FIG. 6B depicts an enlarged view of the epi-structure 106. The distance D may be defined generally as the distance between the edge of the epi-structure 106 within the dummy stressor 312 and the transistor channel 104. The structure of FIG. 6A and FIG. 6B, as well as the other shapes of epi-structure 106 discussed herein, allow D to be reduced, which in turn may increase the efficiency of the stress transfer from the dummy stressor 312 to the transistor channel 104. Although the shapes of the epi-structure 106 shown FIGS. 6A and 6B are shown as trapezoidal shapes, in other embodiments the shape may include any suitable shape, such as polygons, conic sections, etc. The shape of the epi-structure 106 may be chosen to minimize the distance between the dummy stressor 312 and the transistor channel 104 to allow a more efficient transfer of stress. In some embodiments, additional factors such as the ease of deposition, as well as the barrier layer formation process may be used in the choice of the shape of the epi-structure 106.

In some embodiments, an isolation layer referred to as the bottom dielectric isolation layer may be formed over the substrate 102 prior to the creation of the epitaxial stack 301. The bottom dielectric isolation layer may be formed of a suitable dielectric material such as a nitride, oxide or carbide of a semiconductor material. In some embodiments, the material for the bottom dielectric isolation layer may be unsuitable for the formation of the epi-structure 106 so that the epi-structure 106 may form on only selected surfaces such as the transistor channel 104.

Additionally, by forming the epi-structure 106 as separated portions which do not merge, the growth of each of the epi-structure 106 may avoid the introduction of stacking faults and dislocations which may be caused by two or more epitaxial structures merging. In some embodiments, each of the epi-structure 106 may be separately grown on a selected surface of the trench 311, such as the transistor channel 104. Furthermore, even in embodiments where the epi-structure 106 may be formed as separate unmerged portions, the epi-structure 106 may be subject to additional shaping to provide a more efficient transfer of stress. For example, the epi-structure 106 may have additional shaping to reduce the distance between the dummy stressor 312 and the transistor channel 104.

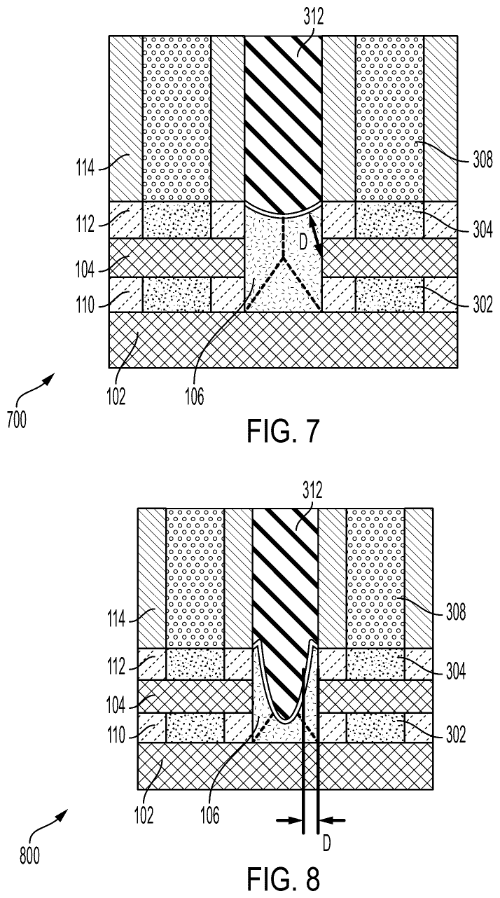

FIG. 7 depicts an alternative version of S560 shown in FIG. 3J, showing a second intermediate structure 800 where the epi-structure 106 is a merged structure. In FIG. 7, the epi-structure 106 is grown large enough that different separate portions have grown into a fully merged structure. In order to increase the transfer efficiency to the transistor channel 104, the epi-structure 106 may be partially reduced, such as by etching to reduce the distance D between the dummy stressor 312 at the edge of the epi-structure 106 and the transistor channel 104. The reduction in distance between the transistor channel 104 and the dummy stressor 312 may thus allow a more efficient transfer of the stress from the dummy stressor 312 and the transistor channel 104.

FIG. 8 depicts an alternative version of FIG. 7, showing a third intermediate structure 900 where the epi-structure 106 is grown large enough that different separate portions have grown into a fully merged structure and then the epi-structure 106 is greatly reduced by a process such as etching. A relatively deep etch may reduce the distance D between the dummy stressor 312 at the edge of the epi-structure 106 and the transistor channel 104 further compared to FIG. 7 and thus provide an increase in the stress transfer efficiency from the dummy stressor 312 to the transistor channel 104. Additionally, the distance D may remain sufficiently high to prevent damage during the formation of the barrier layer by a process such as silicidation.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific example teachings discussed above, but is instead defined by the following claims.

What is claimed is:

1. A device comprising:
a substrate;
a transistor channel located on the substrate, the transistor channel extending in a direction parallel to the substrate;
a first electrode coupled to the transistor channel, the first electrode extending in a direction orthogonal to the substrate;
a second electrode coupled to the transistor channel, the second electrode extending in a direction orthogonal to the substrate and parallel to the first electrode; and
a first epitaxial structure arranged between the transistor channel and the first electrode,
wherein the first epitaxial structure shares a common crystalline orientation with the transistor channel, and wherein the first epitaxial structure separates a surface of the first electrode and a surface of the transistor channel in a direction parallel to the substrate by a distance which varies along the length of the first electrode.

2. The device of claim 1, wherein:
the first epitaxial structure is between the first electrode and the substrate, and
the first epitaxial structure forms a concave surface with respect to the first electrode.

3. The device of claim 1, wherein the second electrode surrounds the transistor channel, forming a gate-all-around transistor.

4. The device of claim 1, further comprising an inner spacer arranged between the first electrode, the second electrode, and the transistor channel,
wherein the first electrode is between the first epitaxial structure and the inner spacer.

5. The device of claim 1, wherein the distance between a surface of the first electrode and a surface of the transistor channel in a direction parallel to the substrate is inversely related to the distance to the substrate in a direction parallel the first electrode.

6. The device of claim 1, wherein:
the first electrode is between the first epitaxial structure and the substrate, and
the first epitaxial structure forms a convex surface with respect to the first electrode.

7. The device of claim 1, further comprising a third electrode, the third electrode coupled to the transistor channel, the third electrode extending in a direction orthogonal to the substrate; and
a second epitaxial structure arranged between the third electrode and the transistor channel,
wherein the first electrode is coupled to the third electrode via the transistor channel.

8. A device comprising:
a substrate having a transistor channel, the transistor channel extending in a direction parallel to the substrate;
a first electrode extending in a direction orthogonal to the substrate and coupled to a first end of the transistor channel;
a second electrode extending in a direction parallel to the first electrode, and coupled to a second end of the transistor channel;
a first epitaxial structure arranged between the first electrode and the first end of the transistor channel, the first epitaxial structure having a thickness varying along a direction parallel with the first electrode; and
a second epitaxial structure arranged between the second electrode and the second end of the transistor channel, the second epitaxial structure having a thickness varying along a direction parallel with the second electrode.

9. The device of claim 8, wherein:
the first epitaxial structure is between the first electrode and the substrate, and
the first epitaxial structure forms a concave surface with respect to the first electrode.

10. The device of claim 8, wherein:
the first electrode is between the first epitaxial structure and the substrate, and
the first epitaxial structure forms a convex surface with respect to the first electrode.

11. The device of claim 8, further comprising a third electrode arranged between the first electrode and the second electrode, the third electrode extending in a direction parallel to the first electrode and the second electrode, and the third electrode coupled to the transistor channel along a medial section between the first end and the second end.

12. The device of claim 8, wherein the transistor channel comprises silicon and wherein the first epitaxial structure comprises silicon.

13. The device of claim 8, wherein a dielectric material is arranged between the transistor channel and the substrate.

14. A method comprising:
forming an epitaxial stack on a substrate, the epitaxial stack including a transistor channel;
removing portions of the epitaxial stack to form a trench exposing at least a portion of the substrate;
forming an epitaxial structure within the trench, the epitaxial structure contacting the transistor channel;
imparting a compressive stress along the length of the transistor channel via the epitaxial structure; and
depositing a first electrode in the trench.

15. The method of claim 14, wherein forming the epitaxial structure includes growing an epitaxial layer which is non-contiguous, wherein the epitaxial structure forms a convex surface with respect to the first electrode, and wherein the first electrode is between the epitaxial structure and the substrate.

16. The method of claim 14, wherein forming the epitaxial structure includes growing an epitaxial layer which is contiguous, wherein the epitaxial structure forms a concave surface with respect to the first electrode, and wherein the epitaxial structure is between the first electrode and the substrate.

17. The method of claim 14, imparting the compressive stress on the epitaxial structure along the length of the transistor channel via the epitaxial structure includes forming a dummy stressor within the trench, the dummy stressor imparting compressive stress on the epitaxial structure, the epitaxial structure transferring the compressive stress to the transistor channel.

18. The method of claim 14, wherein forming the epitaxial structure includes growing an epitaxial layer and etching the epitaxial layer to reduce a distance between the transistor channel and the first electrode.

19. The method of claim 14, wherein the first electrode is a source electrode or a drain electrode.

20. The method of claim 14, further comprising, after imparting the compressive stress along the length of the transistor channel via the epitaxial structure, forming a barrier layer on a surface of the epitaxial structure, and
wherein the first electrode contacts the barrier layer.
